(19) United States
(12) Patent Application Publication
(10) Pub. No.: US 2010/0081295 A1
(43) Pub. Date: Apr. 1, 2010

(54) PROCESS MODEL EVALUATION METHOD, PROCESS MODEL GENERATION METHOD AND PROCESS MODEL EVALUATION PROGRAM

(76) Inventors: Masanori TAKAHASHI, Yokohama-shi (JP); Masaki Satake, Yokohama-shi (JP); Satoshi Tanaka, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/548,955

(22) Filed: Aug. 27, 2009

(30) Foreign Application Priority Data
Sep. 30, 2008 (JP) 2008-255636

(51) Int. Cl. H01L 21/027; G03F 7/20; G06F 17/50

(52) U.S. Cl. 438/800; 430/30; 716/21; 716/19; 257/E21.023

(57) ABSTRACT

According to an aspect of the present invention, there is provided a method for evaluating a process model, the method including: acquiring, for each of given patterns, a dimensional difference amount between: a first pattern that is formed by actually applying a process onto a corresponding one of the given patterns; and a second pattern that is calculated by applying a process model modeling the process to the corresponding one of the given patterns; and evaluating the process model based on an evaluation index, the evaluation index being based on the number of the patterns at which the dimensional difference amount is equal to or less than a threshold value.

### CROSS-REFERENCE TO RELATED APPLICATIONS

This application claims priority from Japanese Patent Application No. 2008-255636 filed on Sep. 30, 2008, the entire contents of which are incorporated herein by reference.

### BACKGROUND OF THE INVENTION

1. Field of the Invention

An aspect of the present invention relates to a process model evaluation method for evaluating process models obtained by modeling various processes in a semiconductor manufacturing process, a process model generation method, and a process model evaluation program.

2. Description of the Related Art

In order to form a micropatterned semiconductor circuit pattern as designed, it is indispensable to design a mask pattern in consideration of process proximity effects in processes (e.g., a mask generation process, a lithography process, and an etching process) for forming a circuit pattern.

As a process proximity effect correction method, a model-based correction is proposed (see, e.g., JP-2000-232057-A). In the model-based correction, it is necessary to utilize a model accurately representing the relationship between a designed mask pattern and an actually-formed pattern formed through the various processes performed using mask pattern data that represents the designed mask pattern according to various process conditions, such as used materials and apparatuses and instrument parameters.

Sometimes, to evaluate the model, the root mean square (RMS) of the dimensional difference between a calculated pattern calculated from the model and a actually-formed pattern is used as an evaluation index.

According to this evaluation method, in the case where most part of patterns have small dimensional difference and an small part of patterns have large dimensional difference, the value of the evaluation index for all patterns is degraded. Accordingly, there is a fear that an appropriate model evaluation cannot be performed.

### SUMMARY OF THE INVENTION

According to an aspect of the present invention, there is provided a method for evaluating a process model, the method including: acquiring, for each of given patterns, a dimensional difference amount between: a first pattern that is formed by actually applying a process onto a corresponding one of the given patterns; and a second pattern that is calculated by applying a process model modeling the process to the corresponding one of the given patterns; and evaluating the process model based on an evaluation index, the evaluation index being based on the number of the patterns at which the dimensional difference amount is equal to or less than a threshold value.

According to another aspect of the present invention, there is provided a method for generating a process model, the method including: generating a process model so that an evaluation index satisfies a given condition, the evaluation index being based on the number of patterns at which an dimensional difference between a first pattern and a second pattern is smaller than or equal to a threshold value, the first pattern being formed by actually applying a process onto each of given patterns, the second pattern being calculated by applying the process model modeling the process onto each of the given patterns.

According to still another aspect of the preset invention, there is provided a computer-readable medium storing a program for causing a computer to perform: the aforementioned method.

According to still another aspect of the preset invention, there is provided a method for evaluating a process model, the method including: generating a process model corresponding to a manufacturing process; actually forming a plurality of first patterns from a plurality of given patterns by applying the manufacturing process; virtually forming a plurality of second patterns from the plurality of given patterns by applying the process model; respectively comparing the first patterns and the second patterns, thereby acquiring a plurality of dimensional difference amounts; respectively comparing the dimensional difference amounts with a threshold value; counting the number of patterns at which the dimensional difference amount is smaller than or equal to the threshold value; and re-generating the process model based on the counted number.

According to still another aspect of the preset invention, there is provided a method for generating a pattern, the method including: generating a pattern to which a process is to be applied; preparing a process model that corresponds to the process and that has been evaluated by the aforementioned method; predicting a finished pattern by applying the process model onto the pattern; determining whether the predicted finished pattern satisfies a given condition; and if the predicted finished pattern does not satisfy the given condition, modifying the pattern.

According to still another aspect of the preset invention, there is provided a method for manufacturing a semiconductor device, the method including: preparing a pattern by the aforementioned method; and applying a process onto the pattern, thereby manufacturing the semiconductor process.

### BRIEF DESCRIPTION OF THE DRAWINGS

FIG. 1 is a flowchart illustrating a process model evaluation method according to an embodiment.

FIG. 2 is a graph illustrating the number of patterns at each value of the dimensional difference amount thereof from a pattern calculated from a model according to the embodiment.

FIG. 3 is a graph illustrating an evaluation index used in the model evaluation method according to the embodiment.

FIG. 4 is a graph illustrating the comparison in accuracy between a process model satisfying a model evaluation index according to the embodiment, and a process model satisfying a related model evaluation index.

FIG. 5 is a diagram illustrating a model evaluation apparatus according to the embodiment.

### DETAILED DESCRIPTION OF THE INVENTION

Hereinafter, an embodiment of the invention is described in detail with reference to the accompanying drawings.

### Embodiment

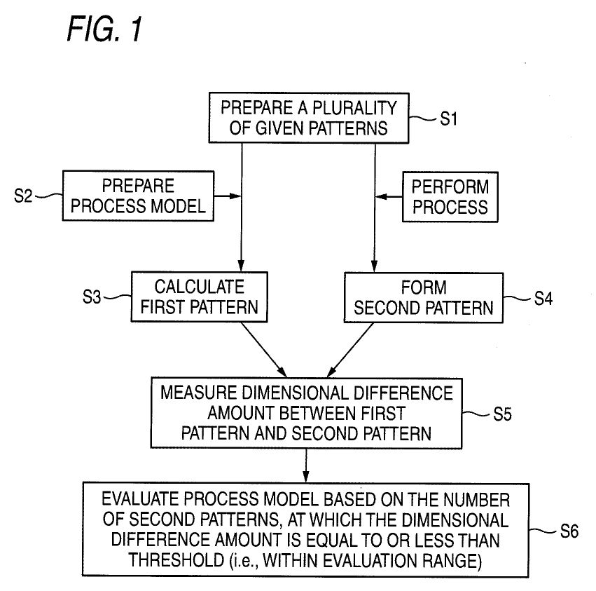

A process model evaluation method according to the embodiment of the invention is described below by referring to FIG. 1. FIG. 1 is a flowchart illustrating the process model evaluation method according to the present embodiment.

First, as shown in step S1 in FIG. 1, given patterns to be utilized in a semiconductor device manufacturing process are prepared. The given patterns include a plurality of individual patterns. The patterns include a design pattern representing a circuit pattern of a semiconductor device, a mask pattern to be formed on a mask substrate, a drawing pattern for drawing a mask pattern, an optical image intensity pattern (optical image intensity distribution) formed by transferring a mask pattern onto a semiconductor substrate by light irradiation using an exposure device, a resist pattern obtained by developing a resist film, and a processed film pattern formed by etching a base layer (processing-target film) using a resist pattern as a mask. The design pattern, the resist pattern and the like are densely arranged at intervals of several tens of nanometers and have widths of several tens of nanometers to the extent that optical proximity effects occur in a lithography process, for example.

Next, as shown in step S2 in FIG. 1, a process model obtained by modeling a semiconductor device manufacturing process is prepared.

As the semiconductor device manufacturing process, at least one of the mask manufacturing process, the lithography process and the etching process is evaluated and generated as the process model, for example.

The mask manufacturing process is a process of forming a mask pattern on a mask substrate using a drawing apparatus or the like based on drawing data that is generated from the design pattern corresponding to a circuit pattern of a semiconductor device. The mask manufacturing process includes a drawing process of drawing drawing-data on a film material provided on a mask substrate by use of a drawing apparatus, and a transfer process of forming a mask pattern by transferring a drawing pattern drawn on a film material onto a mask substrate, through a development process and an etching process.

The lithography process includes an exposure process, a baking process and a development process. In the exposure process, a pattern (optical image) is formed on a resist film provided on a semiconductor substrate by transferring a mask pattern formed on a mask onto the resist film by use of an exposure apparatus. In the baking process, an acid generated in the resist film in the exposure process is diffused by baking. In the development process, a resist pattern is formed by supplying a developer to dissolve a part of the resist film, after baking.

In the etching process, a processed film pattern is formed by processing a processing-target film by use of the resist pattern formed thereon as a mask. The processed film pattern includes circuit patterns of a gate electrode, wiring and the like.

A process model is obtained by modeling such a manufacturing process, and is a conversion model indicating the relationship between a given pattern and a result pattern obtained by applying the manufacturing process thereto. The given pattern is, e.g., the shapes, the widths and the space widths of various processes formed by the above semiconductor device manufacturing process.

In the following description, a process model evaluation method for a lithography model obtained by modeling a lithography process is mainly described.

As shown in step S3 in FIG. 1, a predicted resist pattern (first pattern) to be formed in a resist film is calculated from the pattern data of the mask patterns (given patterns) prepared in step S1. The mask patterns include a plurality of individual patterns.

On the other hand, as shown in step S4 in FIG. 1, an actual resist pattern (second pattern) formed in a resist film on a semiconductor substrate is obtained by actually performing a lithography process using the mask whose mask pattern corresponds to the mask patter prepared in step S1.

Next, as shown in step S5 in FIG. 1, the predicted resist pattern (first pattern) obtained by calculation in step S3 is compared with the actual resist pattern (second pattern) obtained in step S4 to measure a dimensional difference amount therebetween.

An example of measurement of the dimensional difference amount is described below. First, a measurement edge or point is set on the pattern contour of a mask pattern to be a subject of simulation and an actual process. Subsequently, on each of the resist patterns respectively obtained in steps S3 and S4, a measurement edge or point corresponding to the above-mentioned measurement edge or point is set. Finally, the distance between measurement edges or points of the resist patterns obtained in steps S3 and S4 is measured, and the measured distance is set as the dimensional difference amount therebetween.

The dimensional difference amount may be obtained by the other methods. For example, the dimensional difference amount may be obtained from the distance between arbitrary corresponding edges or points respectively set on the pattern contours of the resist patterns obtained in steps S3 and S4, or from the minimum distance between corresponding edges or points respectively set on the pattern contours thereof.

Next, as shown in step S6 in FIG. 1, the accuracy of the lithography model is evaluated based on the dimensional difference amount obtained in step S5. That is, the model is evaluated based on the number of the second patterns, at which the dimensional difference amount is equal to or less than a threshold. Hereinafter, processing performed in step S6 is further described.

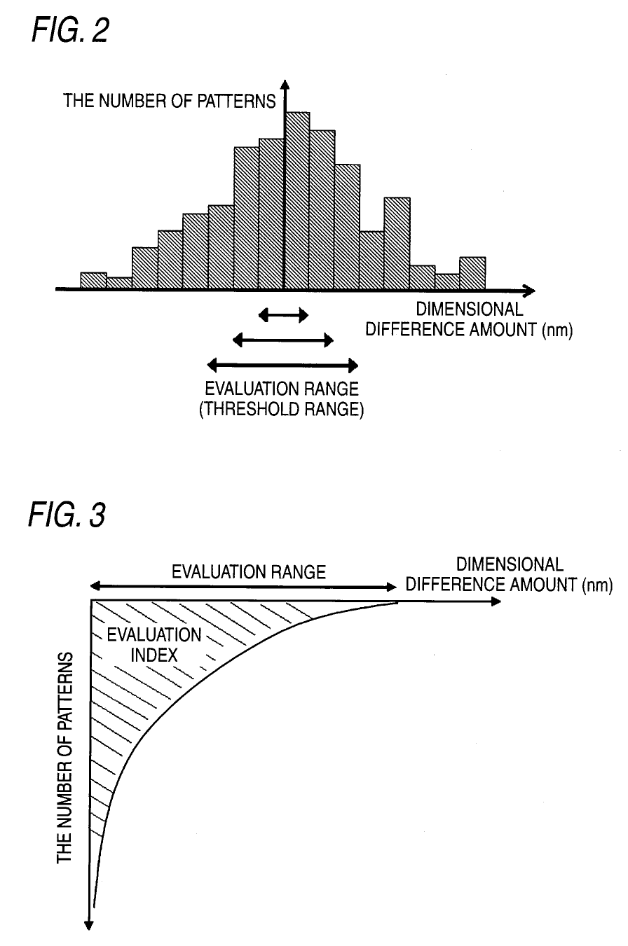

FIG. 2 is a graph illustrating the number of patterns (dimensional difference generating patterns), which is determined to generate the dimensional difference, at each dimensional difference amount. The abscissa axis of FIG. 2 represents the dimensional difference amount. The ordinate axis of FIG. 2 represents the number of dimensional difference generating patterns. In the graph, the dimensional difference amount, at which the number of the dimensional difference generating patterns is maximized, is located at the center of the abscissa axis. Each two-headed-arrow drawn closely to the abscissa axis in FIG. 2 represents a threshold range (evaluation range) of the dimensional difference amount of the pattern, which is taken into consideration to determine an evaluation index. That is, the evaluation index is obtained based on the number of patterns whose dimensional differences are within each evaluation range (each range of the dimensional difference amount equal to or less than an associated threshold).

The evaluation index for evaluation of the process model is obtained by an evaluation formula:

$$( {\sum }_{1}^{M} ( 1 - \frac{n}{N} ) )$$

based on the relationship between the number of the dimensional difference generating patterns and the dimensional difference amount, which is illustrated in FIG. 2. In this evaluation formula, “M” designates the maximum value of evaluation numbers (1, 2, 3, . . . ) respectively corresponding to all evaluation ranges of the dimensional difference amount (nm), “i” denotes an evaluation number corresponding to each evaluation range of the dimensional difference amount (nm), “N” represents the number of all patterns to which the model is applied, and “n” designates the number of patterns whose dimensional differences generated by applying the model thereto are within the evaluation range.

FIG. 3 illustrates an evaluation index calculated by this evaluation formula. The abscissa axis of FIG. 3 represents the dimensional difference amount. The ordinate axis of FIG. 3 represents the number of dimensional difference generating patterns. A hatched region in FIG. 3 corresponds to the evaluation index obtained by the above evaluation formula. The evaluation index always has a positive value. The smaller the value of the dimensional difference becomes, the smaller the evaluation index becomes. Consequently, the smaller the evaluation index becomes, the higher the accuracy of the process model becomes.

The process model can be evaluated by performing the above process based on the process model evaluation method according to the present embodiment.

According to the related art, the RMS of the dimensional difference is used as the evaluation index. Thus, a pattern, whose dimensional difference amount from the pattern actually subjected to the process is large, has to be dominant in the evaluation of the entire model. Consequently, appropriate model evaluation cannot be performed. However, the model evaluation method according to the present embodiment determines the evaluation index based on the number of the dimensional difference generating patterns that generate the dimensional difference amount, which is equal to or less than a given threshold. Thus, the pattern, whose dimensional difference amount from the pattern actually subjected to the process is large, is not dominant in the evaluation of the entire model. There is no fear that the evaluation of the model becomes inaccurate according to the dimensional difference amount.

A process model is generated through the process model evaluation method according to the present embodiment, so that the evaluation index meets a desired condition. At that time, if necessary, the evaluation of the process model is repeated. Consequently, a modified process model is generated by changing, as needed, a given parameter of the process model such that the value of the evaluation index is equal to or less than a desired value.

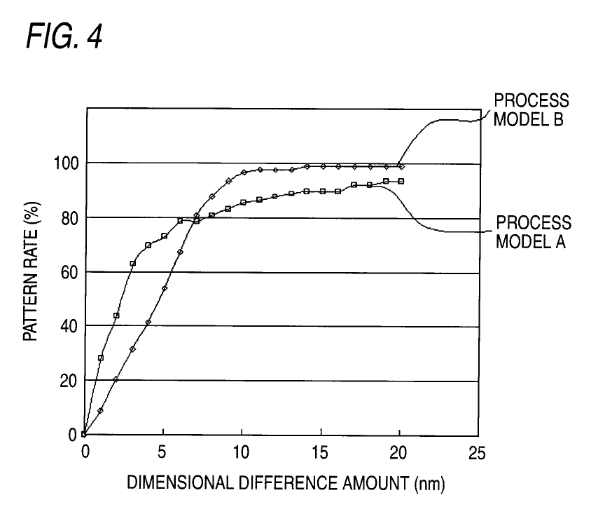

As shown in FIG. 4, accuracy of a process model (hereunder referred to as a process model A) generated to meet conditions concerning the evaluation index of the process model evaluation method according to the embodiment is described below by being compared with that of a process model (hereunder referred to as a process model B) generated to meet conditions concerning the RMS-based evaluation index according to the related-art process model evaluation method. The abscissa axis of FIG. 4 represents a rate of the accumulated number of patterns, whose amounts of the dimensional difference are equal to or less than a given amount, to all patterns to which the model is applied. The ordinate axis thereof represents the dimensional difference amount of the pattern.

In the comparison therebetween illustrated in FIG. 4, 140 mask patterns are employed as the subjects of the comparison. Thus, the dimensional difference of each of the patterns respectively calculated corresponding to each subject according to both the process models A and B from a real pattern obtained by applying an actual process thereto is measured. Then, accuracies of both the models are compared with each other. According to the method of evaluating the process model A, the evaluation index is set by assuming that the absolute value of the dimensional difference in the evaluation range is equal to or less than 50 nm.

According to FIG. 4, 80% or slightly less of the patterns calculated using the process model A is within a range of the dimensional difference, which is equal to or less than 5 nm. On the other hand, only 60% or slightly less of the patterns calculated using the process model B is within a range of the dimensional difference, which is equal to or less than 5 nm. That is, according to the process model A, patterns, whose dimensional differences are small from the pattern obtained by applying an actual process to each of a larger number of subject patterns, can be predicted, as compared with the process model B. It is understood that the model A represents the actual process more accurately.

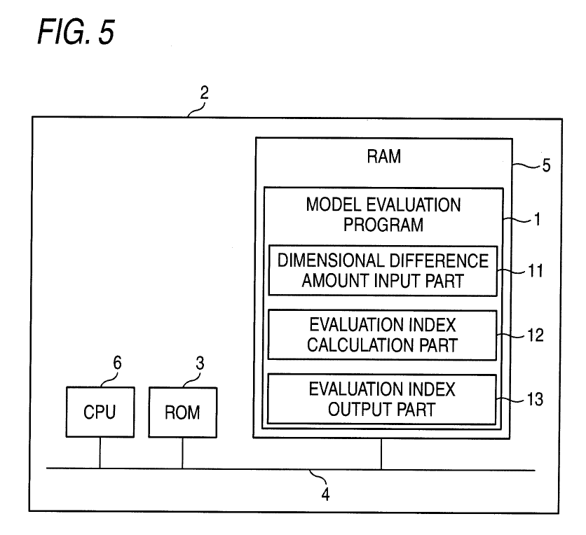

The process model evaluation method and the process model generation method according to the present embodiment can be performed using a process model evaluation apparatus (system) and a process model generation apparatus (system). Each of the process model evaluation apparatus and the process model generation apparatus includes a program that executes the above various steps. FIG. 5 illustrates an example of the configuration of the process mode evaluation apparatus.

As illustrated in FIG. 5, the process model evaluation program 1 is stored in a read-only memory (ROM) 3 of the process model evaluation apparatus 2. The process model evaluation program 1 is loaded onto a random access memory (RAM) 5 through a bus line 4. A central processing unit (CPU) 6 executes the program 1 loaded onto the RAM 5. For example, in the process model evaluation apparatus 2, the CPU 6 reads the process model evaluation program 1 from the ROM 3 and develops the read program 1 in a program storage area in the RAM 5. Thus, the CPU 6performs various processes. The CPU 6 causes the data storage area formed in the RAM 5 to store various data generated in the various processes.

The process model evaluation program 1 to be executed in the process model evaluation apparatus 2 according to the present embodiment includes a dimensional difference amount input part 11, an evaluation index calculation part 12, and an evaluation index output part 13. An evaluation index is calculated by the evaluation index calculation part 12 based on a dimensional difference amount input to the dimensional difference amount input part 11. An obtained result is output by the evaluation index output part 13. Each of the above parts is loaded onto and developed on a main memory device.

The model evaluation program 1 may be stored in a computer connected to a network such as the Internet, and the process model evaluation apparatus 2 may be configured to acquire the model evaluation program 1 by downloading from the computer through the network. The model evaluation program 1 to be executed in the process model evaluation apparatus 2 may be distributed via the network. The model evaluation program 1 may be preliminary incorporated into the ROM or the like.

In the foregoing description of the present embodiment, calculation of the resist pattern from the mask pattern using the lithography process model as the process model is exemplified. However, a process model other than the lithography process model can be used as the process model. For example, a pattern (first pattern) formed on the mask is calculated from the drawing data using the mask manufacturing process model as the process model. The calculated pattern (first pattern) is compared with the pattern (second pattern) formed on the processing-target film by actually applying the mask manufacturing process thereto, so that the process model is evaluated, thereby generating the process model so as to meet the evaluation index. Similarly, a pattern (first pattern) formed on the processing-target film on the semiconductor substrate can be calculated by using the etching process model as the process model. The calculated pattern (first pattern) is compared with the pattern (second pattern) formed on the processing-target film by actually applying the etching process thereto, so that the process model is evaluated, thereby generating the process model so as to meet the evaluation index.

As the semiconductor device manufacturing process, two or more of the mask manufacturing process, the lithography process and the etching process may be evaluated and generated as the process model.

On the other hand, apart of each of the mask manufacturing process, the lithography process, and the etching process can be evaluated and generated as the process model. For example, each of a drawing process and a transfer process are a part of the mask manufacturing process. In the drawing process, the drawing data is drawn on a film material on the mask substrate. In the transfer process, a mask pattern is formed by transferring the drawing pattern drawn on the film material formed on the mask substrate. For example, each of an exposure process, a baking process and a development process are a part of the lithography process. In the exposure process, a pattern (optical image) is formed on the resist film by an exposure apparatus. In the baking process, the resist film is baked after the exposure. In the development process, a resist pattern is formed by supplying a developer to a resist film.

### Another Embodiment

A method for manufacturing a semiconductor device according to another embodiment of the invention is described below.

First, a pattern as an applying object of a manufacturing process is prepared. For example, the prepared pattern is a design pattern for a semiconductor integrated circuit or a mask pattern to be formed on a mask. Then, a process model modeling the manufacturing process is applied to the prepared pattern to predict a finished pattern.

Next, the predicted finished pattern acquired by applying the process model onto the prepared pattern and a target finished pattern ideally acquired from the prepared pattern are compared. If the comparison result satisfies a given condition (e.g., if the dimensional difference amount therebetween is equal to or smaller than the threshold value), the prepared pattern is determined as to a pattern to which the manufacturing process is actually applied. If the comparison result does not satisfy the given condition, until the condition is satisfied, there are repeated (1) modifying of the prepared pattern and (2) changing of the process condition in the applied manufacturing process.

Then, the manufacturing process is actually applied to the acquired pattern after the comparison process, thereby manufacturing a semiconductor device.

According to an aspect of the present invention, there is provided a process model evaluation method and a process model evaluation program, which can appropriately evaluate a process model, and a process model generation method which can appropriately generate a process model.

What is claimed is:

1. A method for evaluating a process model, the method comprising:
acquiring, for each of given patterns, a dimensional difference amount between:
a first pattern that is formed by actually applying a process onto a corresponding one of the given patterns; and
a second pattern that is calculated by applying a process model modeling the process to the corresponding one of the given patterns; and
evaluating the process model based on an evaluation index, the evaluation index being based on the number of the patterns at which the dimensional difference amount is equal to or less than a threshold value.

2. The method according to claim 1,
wherein the evaluation index is based on a sum of the numbers of the patterns at which the dimensional difference amount is equal to or less than the threshold value.

3. The method according to claim 1,
wherein the threshold value is less than a maximum value of the dimensional difference amounts.

4. The method according to claim 1, further comprising:
re-generating the process model so that the evaluation index satisfies a given condition.

5. The method according to claim 1,
the process includes at least one process selected from a group consisting of:
a mask manufacturing process;
a lithography process; and
an etching process.

6. The method according to claim 1,
wherein the first pattern is acquired by:
preparing a mask in which a mask pattern corresponding to the given pattern is formed;
exposing the mask, thereby transferring the mask pattern therein onto a resist film on a semiconductor substrate; and
developing the resist film, thereby forming the first pattern, and
wherein the second pattern is acquired by:
preparing a mask pattern data corresponding to the mask pattern; and
calculating the second pattern based on the mask pattern data:

7. The method according to claim 1,
the step of acquiring the dimensional difference amount includes:
setting a measurement edge on a contour of the first pattern;
setting a measurement edge on a corresponding position of the second pattern; and
acquiring a distance between the measurement edge on the first pattern and the measurement edge on the second pattern.

8. The method according to claim 1,
the step of acquiring the dimensional difference amount includes:
setting a measurement point on a contour of the first pattern;
setting a measurement point on a corresponding position of the second pattern; and
acquiring a distance between the measurement point on the first pattern and the measurement point on the second pattern.

9. The method according to claim 1,
wherein the evaluation index is calculated from Σi M(1−n/N), M designating a maximum value of a evaluation range, i designating a value of the dimensional difference amount, N designating the number of patterns, n designating the number of patterns whose dimensional difference amounts are within the evaluation range.

10. A method for generating a process model, the method comprising:
generating a process model so that an evaluation index satisfies a given condition, the evaluation index being based on the number of patterns at which an dimensional difference between a first pattern and a second pattern is smaller than or equal to a threshold value, the first pattern being formed by actually applying a process onto each of given patterns, the second pattern being calculated by applying the process model modeling the process onto each of the given patterns.

11. A computer-readable medium storing a program for causing a computer to perform:
the method according to claim 1.

12. A method for evaluating a process model, the method comprising:
generating a process model corresponding to a manufacturing process;
actually forming a plurality of first patterns from a plurality of given patterns by applying the manufacturing process;
virtually forming a plurality of second patterns from the plurality of given patterns by applying the process model;
respectively comparing the first patterns and the second patterns, thereby acquiring a plurality of dimensional difference amounts;
respectively comparing the dimensional difference amounts with a threshold value;
counting the number of patterns at which the dimensional difference amount is smaller than or equal to the threshold value; and
re-generating the process model based on the counted number.

13. A method for generating a pattern, the method comprising:
generating a pattern to which a process is to be applied;
preparing a process model that corresponds to the process and that has been evaluated by the method according to claim 1;
predicting a finished pattern by applying the process model onto the pattern;
determining whether the predicted finished pattern satisfies a given condition; and
if the predicted finished pattern does not satisfy the given condition, modifying the pattern.

14. The method according to claim 13,
wherein the pattern is a circuit design pattern of a semiconductor device.

15. The method according to claim 13,
wherein the pattern is a mask pattern to be formed in a mask.

16. The method according to claim 13,
wherein the step of determining determines whether a dimensional difference amount between the predicted finished pattern and a target finished pattern that is ideally acquired from the pattern is within a given range.

17. A method for manufacturing a semiconductor device, the method comprising:
preparing a pattern by the method according to claim 13; and
applying a process onto the pattern, thereby manufacturing the semiconductor process.
